(19) United States
(12) Patent Application Publication
(10) Pub. No.: US 2026/0278194 A1
(43) Pub. Date: Sep. 17, 2026

(54) AERONAUTICAL VEHICLE COLLABORATION SERVICE SUPPORTING VIRTUAL MODELS

(71) Applicant: The Boeing Company, Arlington, VA (US)

(72) Inventors: Robert B. Santoso, Anaheim Hills, CA (US); Kenneth Khoi Dang, Lynnwood, WA (US)

(21) Appl. No.: 19/080,041

(22) Filed: Mar. 14, 2025

(51) Int. Cl. G06F 30/15

(52) U.S. Cl. CPC G06F 30/15

(57) ABSTRACT

A computing system and a method performed by the computing system enables collaboration between various entities associated with operation of aeronautical vehicles (AVs). An AV-specific identifier is received that identifies a subject AV of a class of AV. A class-specific virtual model for the class of AV is retrieved based on the AV-specific identifier. An AV-specific data item to be associated with the subject AV is received in which AV-specific data item distinguishes the subject AV from other AVs of the class of AV. An AV-specific virtual model is generated by augmenting the class-specific virtual model with the AV-specific data item to obtain the AV-specific virtual model of the subject AV that incorporates the AV-specific data item. The AV-specific virtual model is output for presentation as a graphical representation of the subject AV. The AV-specific virtual model can be updated based on subsequent AV-specific data items that are received.

### FIELD

A disclosed invention relates generally to a computer-implemented collaboration service for aeronautical vehicles that supports virtual models.

### BACKGROUND

Aeronautical vehicles, including fixed-wing aircraft and rotary-wing aircraft, rely on maintenance and repair tasks performed by technicians to address or mitigate issues that can arise through operation of the vehicles. Various entities can be involved in the operation, maintenance, and repair of aeronautical vehicles, including manufacturers, fleet operators, technicians, and regulatory bodies. These entities can each host on their own set of personnel and data systems as part of operating, repairing, and maintaining aeronautical vehicles. The existence of diverse and separately maintained data system and personnel across such entities increases the complexity of operating, maintaining, and repairing aeronautical vehicles.

### SUMMARY

A computing system and a method performed by the computing system enables collaboration between various entities associated with operation, maintenance, and repair of aeronautical vehicles (AVs). According to an example, an AV-specific identifier is received that identifies a subject AV of a class of AV. A class-specific virtual model for the class of AV is retrieved based on the AV-specific identifier. An AV-specific data item to be associated with the subject AV is received in which AV-specific data item distinguishes the subject AV from other AVs of the class of AV. An AV-specific virtual model is generated by augmenting the class-specific virtual model with the AV-specific data item to obtain the AV-specific virtual model of the subject AV that incorporates the AV-specific data item. The AV-specific virtual model is output for presentation as a graphical representation of the subject AV. The AV-specific virtual model can be updated based on subsequent AV-specific data items that are received.

### BRIEF DESCRIPTION OF THE DRAWINGS

FIG. 1 a schematic diagram depicting an example operating environment that includes a computing system.

FIG. 2 is a flow diagram depicting an example method that can be performed by the computing system of FIG. 1

FIG. 3 schematically depicts an example graphical user interface that can form part of a service interface of FIG. 1.

FIG. 4 is a schematic diagram depicting additional aspects of AV-specific data of FIGS. 1, 2, and 3.

FIGS. 5A and 5B are flow diagrams depicting an example collaborative workflow between various users that is enabled by a service implemented by the computing system of FIG. 1.

FIG. 6 is a schematic diagram depicting additional aspects of the computing system of FIG. 1.

### DETAILED DESCRIPTION

As briefly introduced above, various entities can be involved in the operation, maintenance, and repair of aeronautical vehicles (AVs). A collaboration service hosted by a computing system is disclosed that enables collaboration between these various entities, including personnel associated with manufacturers, fleet operators, technicians, and regulatory bodies. The collaboration service can obtain class-specific data for a class of AV and AV-specific data for a subject AV of the class from various data sources, including users of the service and remote data resources. The collaboration service includes a service interface that can output a graphical representation of a class-specific virtual model for a class of AV and an AV-specific virtual model for a subject AV of the class. Users can associate AV-specific data items for the subject AV with target locations on or within the virtual models, including for particular components, points, or regions with respect to the subject AV. Users can explore class-specific virtual models and AV-specific virtual models via the service interface to access, review, and modify class-specific data and AV-specific data that is associated with a subject AV.

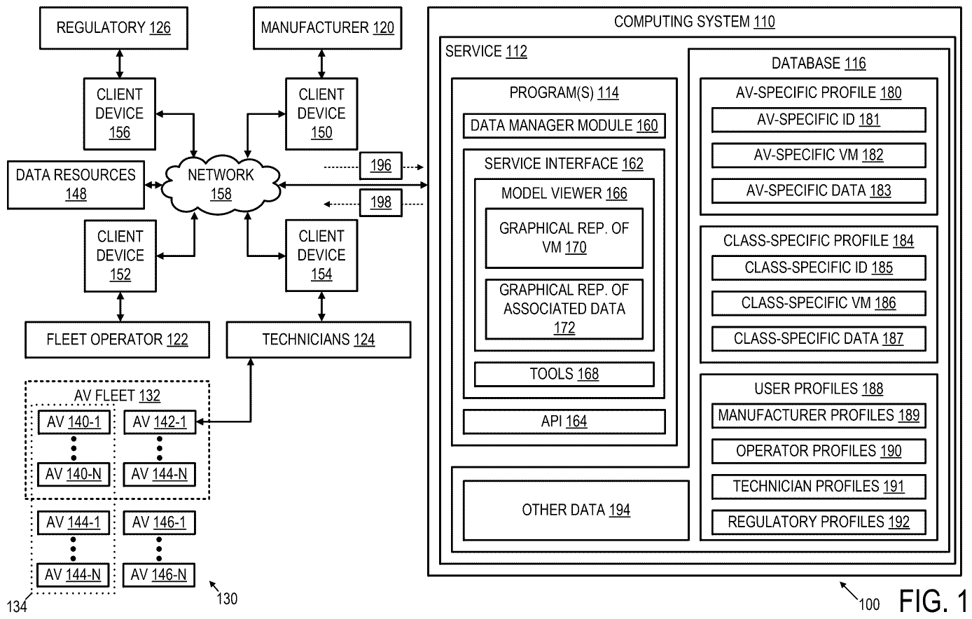

FIG. 1 a schematic diagram depicting an example operating environment 100 that includes a computing system 110 of one or more computing devices. As an example, computing system 110 can take the form of a server system of one or more server computing devices. Computing system 110 hosts a collaboration service 112 that includes one or more programs 114 and a database 116 that enables collaboration between or among various entities associated with operation, maintenance, and repair of AVs, including an AV manufacturer 120, a fleet operator 122, technicians 124, and regulatory bodies 126.

Within operating environment 100, an AV population 130 that includes a plurality of AVs is schematically depicted. AV population 130 includes an AV fleet 132 that is operated by fleet operator 122. AV fleet 132 includes a subset of AVs of AV population 130. In the example, of FIG. 1, AV fleet 132 includes AV 140-1 through AV 140-N, in which the term “N” refers to any suitable quantity of AVs identified herein by reference numeral 140.

AV 140-1 through AV 140-N of fleet 132 each belong to a class of AV 134. A class of AV, as used herein, can refer to a particular production model or configuration of AV. For example, class of AV 134 can refer to a first production model or configuration of passenger jet aircraft manufactured by manufacturer 120. In this example, each of AV 140-1 through AV 140-N takes the form of a respective instance of the production model or configuration of passenger jet aircraft manufactured by manufacturer 120.

Additionally, in the example of FIG. 1, AV fleet 132 includes AV 142-1 through AV 142-N, in which the term “N” refers to any suitable quantity of AVs identified herein by reference numeral 142. AV 142-1 through AV 142-N each belong to a different class of AV from class of AV 134. For example, AV 142-1 can take the form of a second production model or configuration of passenger jet aircraft that differs from the first production model or configuration of passenger jet aircraft of AV 140-1 through AV 140-N represented by class of AV 134. As another example, AV 142-N can take the form of a third production model or configuration of AV that differs from the first and the second production models or configurations of the preceding examples. In at least some examples, AV 142-1 through AV 142-N can be manufactured by one or more different manufacturers than manufacturer 120.

AV population 130 further includes additional AVs that do not form part of AV fleet 132. For example, AV population 130 includes AV 144-1 through AV 144-N that do not form part of AV fleet 132, in which the term “N” refers to any suitable quantity of AVs identified herein by reference numeral 144. In this example, AV 144-1 through AV 144-N each belong to class of AV 134, which also includes AV 140-1 through AV 140-N. While AV 144-1 through AV 144-N are of the same class of AV as AV 140-1 through AV 140-N, AV 144-1 through AV 144-N do not form part of AV fleet 132 and are operated by one or more fleet operators that differ from fleet operator 122.

AV population 130 further includes AV 146-1 through 146-N, in which the term “N” refers to any suitable quantity of AVs identified herein by reference numeral 146. AV 146-1 through 146-N do not form part of AV fleet 132 and do not belong to AV class 134, in the example of FIG. 1. For example, AV 146-1 through 146-N can be operated by one or more fleet operators that differ from fleet operator 122 and/or are of a different class of AV from AV class 134.

As briefly introduced above, service 112 of computing system 110 enables collaboration between or among AV manufacturer 120, fleet operator 122, technicians 124, and regulatory body 126 with respect to one or more AVs of AV population 130. In some examples, service 112 can be maintained and operated by manufacturer 120 to enable collaboration with respect to AVs manufactured by manufacturer 120. However, it will be understood that service 112 can be maintained and operated by another entity.

Service 112 of computing system 110 can obtain data from various sources within operating environment 100. As an example, service 112 can receive data and provide data to remote data resources 148. In at least some examples, remote data resources 148 can be hosted at a server system that is maintained and operated by or on behalf of an entity that differs from manufacturer 120. As an example, data resources 148 can be maintained and operated by or on behalf of fleet operator 122 as part of managing operations of AV fleet 132. As another example, data resources 148 can be maintained and operated by or on behalf of an AV component manufacturer that differs from manufacturer 120 as part of managing the manufacture and distribution of AV components.

Human personnel, as users of service 112 of computing system 110, can interact with the service via corresponding client devices. In the example of FIG. 1, users that are associated with manufacturer 120 can utilize a client device 150 to interact with service 112; users that are associated with fleet operator 122 can utilize a client device 152 to interact with service 112; users that include or are associated with technicians 124 can utilize a client device 154 to interact with service 112; and users that are associated with regulatory body 126 can utilize a client device 156 to interact with service 112. Client devices 150, 152, 154, and 156 refer to computing devices, such as computer workstations, personal computing devices, and/or server computing devices, as examples. While individual client devices are depicted in FIG. 1, it will be understood that any suitable quantity of client devices can be used by human personnel of AV manufacturer 120, fleet operator 122, technicians 124, regulatory body 126, or other entity.

Communications between or among computing system 110 hosting service 112, client devices 150, 152, 154, and 156, and data resources 148 are enabled via a communications network 158. As an example, communications network 158 can include a wide area network, such as the Internet or a portion thereof. Communications network 158 can include wired and/or wireless networks.

Programs 114 of service 112 include a data manager module 160, a service interface 162, and an application programming interface (API) 164. Data manager module 160 can obtain, process, and store various data at database 114, as described in further detail herein. Additionally, data manager module 160 can manage sending data to and receiving data from remote data resources 148, and client devices (e.g., 150-156) over communications network 158.

Service interface 162 facilitates user interaction with service 112. In some examples, service interface 162 can be hosted at computing system 110, where the service interface can be accessed by client devices (e.g., 150-156) over communications network 158. For example, the client devices can utilize a general-purpose browser program to interact with service interface 162 hosted at computing system 110. In other examples, a client-side instance of service interface 162 can be downloaded and installed at client devices (e.g., 150-156) to enable interaction with a server-side instance of service interface 162 hosted at computing system 110.

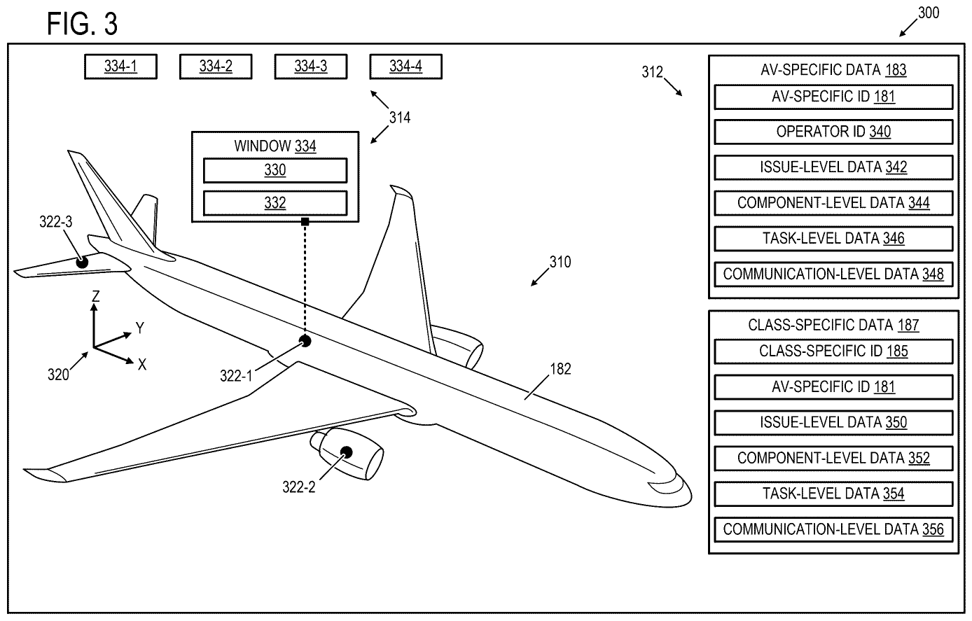

Service interface 162 includes a model viewer 166 and tools 168, described in further detail herein with reference to FIG. 3. Model viewer 166 can output a graphical representation 170 of a virtual model of an AV and a graphical representation 172 of associated data, as described in further detail herein. Tools 168 are operable by users to perform various tasks with respect to service 112, including tasks relating to virtual models of AVs and associated data presented via model viewer 166, tasks relating to operation of database manager module 160, and tasks involving other data stored at database 116.

API 164 of service 112 can be used by other computing devices and computing systems to communicate with the service, including providing data to and retrieving data from database 116. As an example, client-side programs (e.g., applications) operating at client devices 150-156 can communicate with service 112 via API 164. As another example, programs operating at remote computing systems hosting data resources 148 can communicate with service 112 via API 164.

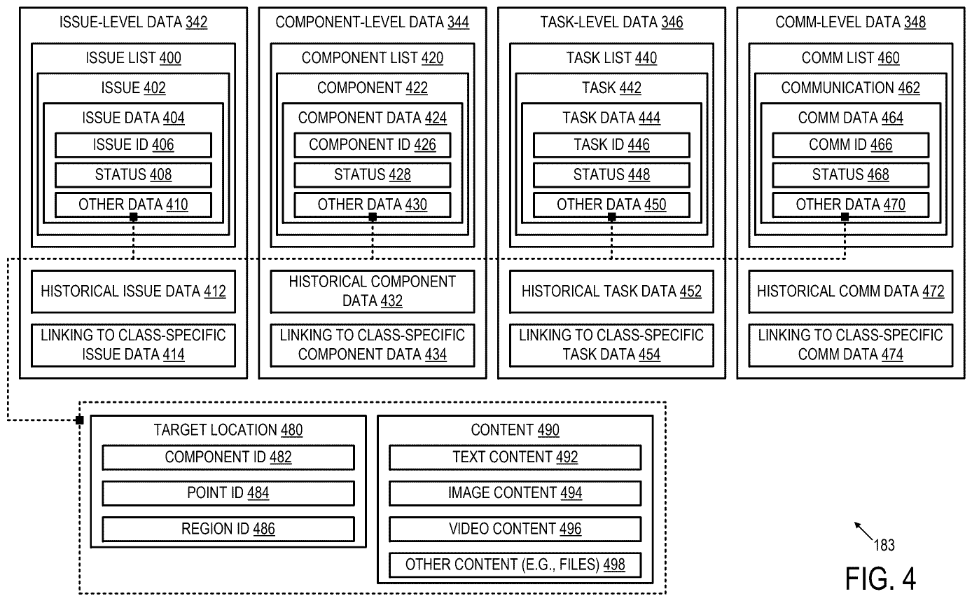

Database 116 can hold various data, examples of which are depicted schematically in FIG. 1, and described in further detail with reference to FIGS. 3 and 4. For example, database 116 includes an AV-specific profile 180 for a particular AV (e.g., 140-1) of AV population 130. Each AV of AV population 130 or a subset thereof can have a corresponding AV-specific profile within database 116. For a subject AV (e.g., 140-1) of AV population 130, AV-specific profile 180 includes an AV-specific identifier (ID) 181 for the AV, an AV-specific virtual model (VM) of the AV, and other AV-specific data 183 for the AV.

Database 116 further includes a class-specific profile 184 for a particular class of AV (e.g., 134). Each class of AV can have a corresponding class-specific profile within database 116. For a subject class of AV (e.g., 134), class-specific profile 184 includes a class-specific identifier 185 for the class of AV, a class-specific virtual model 186 of the class of AV, and other class-specific data 187 for the class of AV.

Database 116 further includes user profiles 188. Each user of service 112 can have a corresponding user profile within user profiles 188. For example, users of service 112 that include or are associated with manufacturer 120 can have manufacturer profiles 189. Users of service 112 that include or are associated with a fleet operator (e.g., 122) can have fleet operator profiles 190. Users of service 112 that include or are associated with technicians 124 can have technician profiles 191. Users that include or are associated with regulatory bodies (e.g., 126) can have regulatory profiles 192. In some examples, access to data of database 116 and/or functionality of service 112 provided by programs 114 can be controlled on a per user profile basis, under an access control system implemented by service 112. For example, each type of profile within user profiles 188 among manufacturer profiles 189, operator profiles 190, technician profiles 191, and regulatory profiles 192 can have different access and control privileges with respect to service 112. Database 116 can further include other data 194, as described in further detail herein.

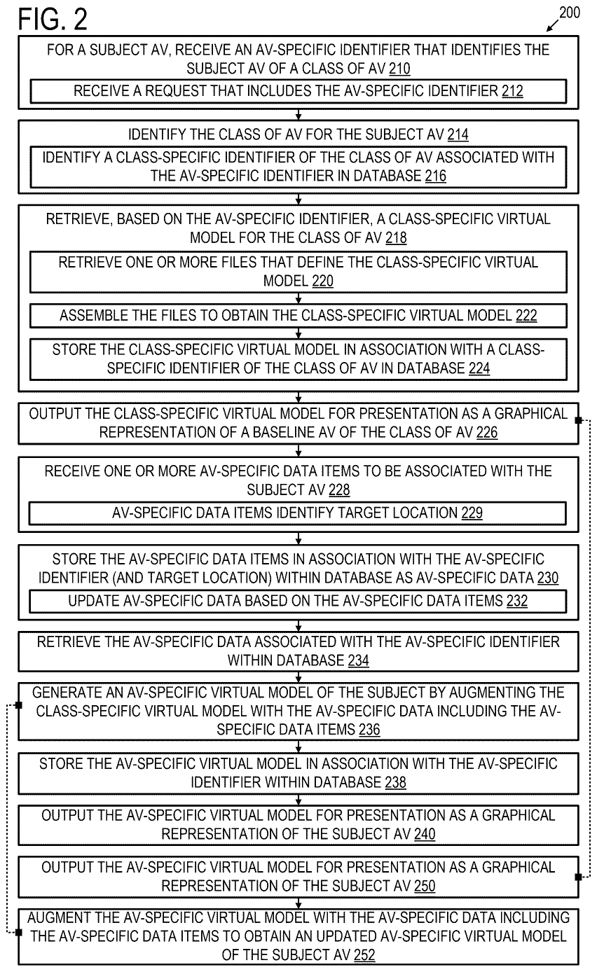

As depicted schematically in FIG. 1, service 112 of computing system 110 can receive AV-specific data items 196 and other data from data resources 148 and client devices 150, 152, 154, and 156 over communications network 158. As described in further detail with reference to FIG. 2, AV-specific data items 196 can be used by service 112 to generate or update AV-specific virtual models (e.g., 182) and other AV-specific data (e.g., 183) stored at database 116. Additionally, AV-specific virtual models (e.g., 182) and other data, indicated schematically at 198, can be output by service 112 of computing system 110 for presentation at client devices 150, 152, 154, and 156.

FIG. 2 is a flow diagram depicting an example method 200 that can be performed by computing system 110 implementing service 112 of FIG. 1. Method 200 describes various operations associated with enabling collaboration between manufacturer 120, fleet operator 122, technicians 124, and regulatory bodies 126 with respect to AVs, including generating and outputting an AV-specific model for a subject AV.

At 210, the method includes, for a subject AV, receiving an AV-specific identifier that identifies the subject AV of a class of AV. Within the context of FIG. 1, as an example, the subject AV can refer to AV 140-1 of class of AV 134 that forms part of AV fleet 132, and the AV-specific identifier received at 210 can refer to AV-specific identifier 181. The AV-specific identifier can take the form of an aircraft registration code (e.g., a tail number), as an example. The AV-specific identifier can include a combination of multiple numbers and/or letters. The AV-specific identifier can be physically marked on an exterior of the subject AV, in at least some examples.

As a first example, the AV-specific identifier can be received by service 112 of computing system 110 from a client device via communications network 158. For example, the AV-specific identifier can be received as part of a request initiated at a client device by a user. In this example, operation 210 can include, at 212, receiving a request that includes the AV-specific identifier. The request received at 212 can be a request to access an AV-specific virtual model (e.g., 182 of FIG. 1) of the subject AV identified by the AV-specific identifier. Additionally or alternatively, the request received at 212 can be a request to associate AV-specific data with an AV-specific profile (e.g., 180 of FIG. 1) for the subject AV within database 116 of FIG. 1. Additionally or alternatively, the request received at 212 can be a request to access AV-specific data (e.g., 183 of FIG. 1) previously associated with the AV-specific profile for the subject AV within database 116.

As a second example, the AV-specific identifier can be received by service 112 of computing system 110 over communications network 158 from a remote data resource (e.g., 148 of FIG. 1) hosted at another computing system. For example, the remote data resource can take the form of a fleet operator database that is operated and maintained by or on behalf of fleet operator 122, and the AV-specific identifier can identify a subject AV (e.g., 140-1) of AV fleet 132 operated by the fleet operator.

At 214, the method includes identifying the class of AV of the subject AV. In some examples, a component (e.g., one or more numbers and/or letters) of the AV-specific identifier can include a class-specific identifier of the class of AV. In other examples, the AV-specific identifier can be associated with the class-specific identifier within a database (e.g., database 116 of FIG. 1). In such examples, the method can include, at 216, identifying a class-specific identifier of the class of AV that is associated with the AV-specific identifier in the database, as part of identifying the class of AV at 214. The class-specific identifier can be retrieved from the database based on the AV-specific identifier.

At 218, the method includes retrieving, based on the AV-specific identifier, a class-specific virtual model for the class of AV identified at 212. The class-specific virtual model retrieved at 214 can take the form of a baseline virtual model for the class of AV to which the subject AV belongs. Class-specific virtual model 186 of FIG. 1 stored at database 116 is an example of the class-specific virtual model that can be retrieved at 218.

In some examples, the class-specific virtual model is stored at a database (e.g., 116 of FIG. 1) in association with the class-specific identifier of the class of AV identified at 216. Additionally or alternatively, the class-specific virtual model is stored at the database in association with the AV-specific identifier. For example, a set of one or more AV-specific identifiers for one or more AVs that belong to the class of AV can be stored in the database in association with the class-specific virtual model. The set of AV-specific identifiers that belong to the class of AV can be updated within the database over time to reflect AVs of the class of AV that are registered with the service as belonging to the class of AV. In each of these examples, the set of AV-specific identifiers that belong to the class of AV can be associated with the class-specific identifier, as previously described with reference to operation 216. Accordingly, in each of the preceding examples, the class-specific virtual model can be retrieved at 218 based on the AV-specific identifier received at 210.

As part of retrieving the class-specific virtual model at 218, the method can include, at 220, retrieving one or more files that define the class-specific virtual model. As an example, the one or more files retrieved at 220 can take the form of computer-aided design (CAD) files that feature a three-dimensional representation of components of an AV or class of AV. In some examples, the class-specific virtual model can be stored in a database (e.g., 116 of FIG. 1) as a plurality of files that are associated with the class-specific identifier (e.g., 185 of FIG. 1). For example, the class-specific virtual model can be formed from a collection of two or more sub-assembly virtual models in which each sub-assembly virtual model is defined by a corresponding file.

Furthermore, as part of retrieving the class-specific virtual model at 218, the method can include, at 222, assembling the plurality of files to obtain the class-specific virtual model. For example, a plurality of sub-assembly virtual models that are defined by the plurality of files can be combined or otherwise merged to obtain the class-specific virtual model at 222. In this example, a reference frame of each sub-assembly virtual model can be translated to a common reference frame as part of assembling the files to obtain the class-specific virtual model. Additionally or alternatively, sub-assembly virtual models can be translated and/or rotated relative to each other to align the sub-assembly virtual models with each other to obtain the class-specific virtual model.

Furthermore, as part of retrieving the class-specific virtual model at 218, the method at 224 can include storing the class-specific virtual model assembled at 222 in association with the class-specific identifier of the class of AV in the database (e.g., database 116 of FIG. 1). For example, in FIG. 1, class-specific virtual model 186 is associated with class-specific identifier 185 in database 116 as part of class-specific profile 184.

The class-specific virtual model assembled at 222 and stored at 224 can be retrieved from the database in subsequent sessions based on the AV-specific identifier and/or class-specific identifier that is associated with the class-specific virtual model. For example, assembling the class-specific virtual model at 222 can be performed for an initial session in scenarios where a class-specific virtual model has not yet been assembled or otherwise established within service 112. For subsequent sessions, the previously assembled class-specific virtual model can be retrieved from the database without repeating the assembly operation at 222.

At 226, the method includes outputting the class-specific virtual model for presentation as a graphical representation of a baseline AV of the class of AV. In the example of FIG. 1, the class-specific virtual model can be output by service 112 of computing system 110 as data 198. For example, service 112 of computing system 110 can output class-specific virtual model 186 by sending the class-specific virtual model to a client device (e.g., 150-156 of FIG. 1) via communications network 158. The client device can receive and present the class-specific virtual model as a graphical representation 170 via an instance of model viewer 166, as an example. The class-specific virtual model can be output at 226 to enable a user to visually verify that the virtual model was properly assembled at 222. In some examples, In some examples, outputting of the class-specific virtual model at 226 is omitted from method 200, such as where an AV-specific virtual model for the subject AV has been previously established at service 112, as further described with reference to method 200.

At 228, the method includes receiving one or more AV-specific data items to be associated with the subject AV. In the example of FIG. 1, the one or more AV-specific data items 196 are received by service 112 of computing system 110. As an example, the one or more AV-specific data items can be received from a client device (e.g., 150-156 of FIG. 1) over communications network 158. As another example, the one or more AV-specific data items can be received from a remote data resource (e.g., 148 of FIG. 1) over communications network 158.

In at least some examples, the one or more AV-specific data items received at 228 identify a target location with respect to the subject AV, as indicated at 229. The target location identified by an AV-specific data item can include a particular component of the subject AV within the class-specific virtual model or the AV-specific virtual model that is generated for the subject AV identified by the AV-specific identifier. Additionally or alternatively, the target location can identify a particular point or particular region on or within the class-specific virtual model or AV-specific virtual model that is generated for the subject AV identified by the AV-specific identifier. As described in further detail with reference to FIGS. 3 and 4, the target location can be identified by user input directed at a graphical representation (e.g., 170 of FIG. 1) of the class-specific virtual model or AV-specific virtual model within service interface 162 of FIG. 1, or by user interaction with tools 168 of service interface 162. In this example, a user can select a component, point, or region on or within the virtual model with which data contained in the AV-specific data items is to be associated by service 112.

In at least some examples, the one or more AV-specific data items received at 228 can distinguish the subject AV from other AVs of the class of AV. As a first example, an AV-specific data item received at 228 can identify issue-level data that describes an issue with respect to the subject AV, which can include an issue to be associated with a target location with respect to the subject AV. As another example, an AV-specific data item received at 228 can identify component-level data with respect to the subject AV, such as an identity, state, status, modification, or repositioning of a target component or a replacement component of the subject AV. As another example, the AV-specific data item can identify task-level data for a task to be performed with respect to the subject AV, such as an investigation, repair, maintenance, or review task to be associated with the subject AV or a state, status, or modification of an existing task. As yet another example, the AV-specific data item can identify communication-level data with respect to the subject AV, such as a communication between two or more users associated with manufacturer 120, fleet operator 122, technicians 124, and/or regulatory body 126 that concern the subject AV. Operation 228 can be omitted in some examples, such as where a client device requests a class-specific model or an AV-specific model of the subject AV for review without providing AV-specific data.

At 230, the method includes storing the one or more AV-specific data items in association with the AV-specific identifier within the database. Additionally, where the one or more AV-specific data items identify a target location, the method at 230 can further include storing the one or more AV-specific data items in association with the target location within the database. As previously described, the target location can include a particular component, point, or region.

As an example, in FIG. 1, the one or more AV-specific data items received at 228 can be stored as AV-specific data 183 of FIG. 1 that is associated with AV-specific identifier 181 in database 116. As part of storing the one or more AV-specific data items at 230, the method at 232 can include updating existing AV-specific data within the database based on the one or more AV-specific data items received at 228. For example, in FIG. 1, AV-specific data 183 existing within database 116 can be updated to incorporate the one or more AV-specific data items received at 228. Updates to the AV-specific data at 232 can include replacement, modification, or augmentation of the AV-specific data that is based on the one or more AV-specific data items received at 228, including target locations identified by the AV-specific data items.

At 234, the method includes retrieving the AV-specific data including the one or more AV-specific data items incorporated therein that is associated with the AV-specific identifier within the database. For example, in FIG. 1, AV-specific data 183, following updates performed at 232 to incorporate the AV-specific data items, can be retrieved from database 116.

At 236, the method includes generating an AV-specific virtual model of the subject AV by augmenting the class-specific virtual model retrieved at 218 with the AV-specific data including the one or more AV-specific data items received at 228 to obtain the AV-specific virtual model. Accordingly, the AV-specific virtual model of the subject AV generated at 236 incorporates the one or more AV-specific data items received at 228. As an example, where the one or more AV-specific data items distinguish the subject AV from other AVs of the class of AV, the AV-specific virtual model can differ from the class-specific virtual model based on the one or more AV-specific data items and/or other AV-specific data existing in the database. For example, a target component of the subject AV that has been modified, moved, or replaced in relation to the class-specific model can be reflected in the graphical representation of the AV-specific virtual model.

In at least some examples, augmenting the class-specific virtual model with an AV-specific data item includes incorporating a graphical identifier that identifies the AV-specific data item into the class-specific virtual model at the target location (e.g., identified at 229) to obtain the AV-specific virtual model. As described in further detail with reference to FIG. 3, graphical identifiers can be presented via a graphical user interface in connection with target locations of the AV-specific virtual model that enable users to access, view, modify, and interact with AV-specific data, including the AV-specific data items associated with the target locations.

At 238, the method includes storing the AV-specific virtual model in association with the AV-specific identifier within the database. For example, in FIG. 1, AV-specific virtual model 182 can be stored in database 116 in association with AV-specific identifier 181. By storing the AV-specific virtual model at 236, operations 214 through 226 can be potentially omitted for subsequent sessions, as the AV-specific virtual model can be retrieved from the database based on the AV-specific identifier without referencing the class-specific virtual model. In other examples, the AV-specific virtual model can be generated for each session from the class-specific virtual model using the AV-specific data, as previously described with reference to operations 218 through 236.

At 240, the method includes outputting the AV-specific virtual model for presentation as a graphical representation of the subject AV. In the example of FIG. 1, the AV-specific virtual model can be output by service 112 of computing system 110 as data 198. The AV-specific virtual model output as a graphical representation of the subject AV incorporates the AV-specific data, including the one or more AV-specific data items received at 228 that were incorporated into the AV-specific virtual model. For example, in FIG. 1, service 112 of computing system 110 can output AV-specific virtual model 182 by sending the AV-specific virtual model to a client device (e.g., 150-156) via communications network 158. The client device can receive and present the AV-specific virtual model as graphical representation 170 of the subject AV via an instance of model viewer 166, as an example.

In a first implementation of method 200, operations 214 through 238 can be performed for a first or initial session to establish the AV-specific virtual model within the database (e.g., 116 of FIG. 1). By establishing the AV-specific virtual model within the database, subsequent requests for the AV-specific virtual model over subsequent sessions can be satisfied by service 112 of FIG. 1 retrieving the AV-specific virtual model that was previously established from database 116 based on the AV-specific identifier, and by sending the AV-specific virtual model to the requesting device (e.g., a client device).

As an illustrative example, where the AV-specific virtual model has been previously established and stored in association with the AV-specific identifier within the database, operation 226 that includes outputting the class-specific virtual model can be replaced by operation 250 in which the existing AV-specific virtual model is output for presentation as a graphical representation of the subject AV in place of the class-specific virtual model. In the example of FIG. 1, the existing AV-specific virtual model can be output by service 112 of computing system 110 as data 198. Additionally, operation 236 in which the AV-specific virtual model is generated by augmenting the class-specific virtual can be replaced by operation 252 in which the existing AV-specific virtual model is augmented with the AV-specific data including the AV-specific data items received at 228 to obtain an updated AV-specific virtual model of the subject AV. In at least some examples, augmenting the existing AV-specific virtual model with an AV-specific data item includes incorporating a graphical identifier that identifies the AV-specific data item into the existing AV-specific virtual model at the target location (e.g., identified at 229) to obtain the updated AV-specific virtual model. As described in further detail with reference to FIG. 3, graphical identifiers can be presented via a graphical user interface in connection with target locations of the AV-specific virtual model that enable users to access, view, modify, and interact with AV-specific data, including the AV-specific data items associated with the target locations. At operation 238, the updated AV-specific virtual model can be stored in association with the AV-specific identifier within the database, and the updated AV-specific model can be output at 240.

Accordingly, for each session following the establishment of the AV-specific virtual model in the database, method 200 can include the following operations: receiving the AV-specific identifier; retrieving, based on the AV-specific identifier, the AV-specific virtual model from the database; receiving one or more subsequent AV-specific data item to be associated with the subject AV; updating the AV-specific virtual model by augmenting the AV-specific virtual model retrieved from the database with the one or more subsequent AV-specific data items to obtain an updated AV-specific virtual model of the subject AV that incorporates the one or more subsequent AV-specific data item; and outputting the updated AV-specific virtual model for presentation as a graphical representation of the subject AV.

In a second implementation of method 200, operations 214 through 236 can be performed to generate the AV-specific virtual model for each session from the class-specific virtual model based on the AV-specific data that incorporates the AV-specific data items. In this second implementation, the AV-specific virtual model can be generated for each session by augmenting the class-specific virtual model with the AV-specific data stored in the database in association with the AV-specific identifier and the AV-specific data items that were received for that session. This approach can reduce the quantity of virtual models that are stored and maintained by service 112 in exchange for a potential increase in computational expense associated with generating the AV-specific virtual model from the class-specific virtual model for each session.

FIG. 3 schematically depicts an example graphical user interface (GUI) 300 that can be presented at a client device, such as client devices 150, 152, 154, and/or 156 of FIG. 1. GUI 300 is an example of service interface 162 of FIG. 1 that includes a model viewer 166 that can present a graphical representation 170 of a virtual model of an AV and a graphical representation 172 of other data. Furthermore, GUI 300 as an example of service interface 162 can include various tools 168 that support or enable user interaction, as described in further detail herein. It will be understood that service interface 162 can take other suitable forms, as GUI 300 is provided as an illustrative example.

GUI 300 includes a graphical representation 310 of AV-specific virtual model 182 of subject AV 140-1 of FIG. 1, as an example. It will be understood that graphical representation 310 can alternatively take the form of a graphical representation of class-specific virtual model 186 of FIG. 1. Graphical representation 310 of FIG. 3 is an example of graphical representation 170 of FIG. 1 that can be presented by model viewer 166 of service interface 162. GUI 300 further includes a graphical representation 312 of associated data, which can include AV-specific data 183 and class-specific data 187, as examples.

GUI 300 further includes graphical tool elements 314 that can enable users to interact with or otherwise access tools 168 of service interface 162. As examples, graphical tool elements 314 can include: a first set of one or more graphical tool elements 334-1 that enable users to input and interact with issue-level data 342 with respect to the subject AV identified by AV-specific identifier 181, a second set of one or more graphical tool elements 334-2 that enable users to input and interact with component-level data 344 with respect to the subject AV identified by AV-specific identifier 181, a third set of one or more graphical tool elements 334-3 that enable users to input and interact with task-level data 346 with respect to the subject AV identified by AV-specific identifier 181, and a fourth set of one or more graphical tool elements 334-4 that enable users to input and interact with communication-level data 348 with respect to the subject AV identified by AV-specific identifier 181.

In the example of FIG. 3, AV-specific virtual model 182 takes the form of a three-dimensional virtual model, and graphical representation 310 of the virtual model is presented at an initial positioning within a three-dimensional reference frame 320. Graphical representation 310 of the virtual model can be repositioned by the user within three-dimensional reference frame 320 by translating and/or rotating the graphical representation in six-degrees of freedom (6DOF), which can include translation in X, Y, Z-coordinate axis directions, and rotation in yaw, roll, pitch directions about the X, Y, Z coordinate axes. Additionally or alternatively, repositioning of the graphical representation 310 can include the user zooming toward or away from the graphical representation 310 within GUI 300. Repositioning of graphical representation 310 of the virtual model can further include generating an exploded view or partial view of the virtual model to enable users to view internal components or other features of the AV. In each of these examples, repositioning of graphical representation 310 can be performed by using tools 168 of FIG. 1 via manipulation of graphical tool elements 314.

Graphical representation 310 depicts various graphical identifiers 322-1, 322-2, 322-3, etc. that can be incorporated into the virtual model at respective target locations. Each of the graphical identifiers (e.g., 322-1, 322-2, 322-3) can identify a target location within three-dimension reference frame 320 with respect to the virtual model that represents the AV. The target location can identify a particular component of the AV within the virtual model, a particular point on or within the virtual model of the AV, or a particular region on or within the virtual model of the AV. As a first example, graphical identifier 322-1 can identify a first component that takes the form of an exterior fuselage panel of the AV. As a second example, graphical identifier 322-2 can identify a second component that takes the form of an engine assembly of the AV. As a third example, graphical identifier 322-3 can identify a particular point or region at a tail of the AV within three-dimensional reference frame 320.

It will be understood that graphical identifiers 322-1, 322-2, 322-3 are depicted schematically in FIG. 3, and can take other suitable forms. For example, graphical identifiers can include or feature highlighting, shading, and/or variation of color applied to components, points, or regions of the virtual model to visually distinguish those components, points, or regions from other portions of the virtual model.

The graphical identifiers (e.g., 322-1, 322-2, 322-3) and/or components of the AV can be selectable by a user within the virtual model of GUI 300 to present associated data 330 and/or graphical tool elements 314, either within a model explorer window 334 or other dedicated location of GUI 300. In FIG. 3, model explorer window 334 is presented for a target location (e.g., a component, point, or region) identified by graphical identifier 322-1. Model explorer window 334 is an example of tools 168 that can enable users to view data and interact with particular components, points, or regions of the virtual model. Data 330 can include portions of AV-specific data 183 and/or class-specific data 187 that is associated with a target location with respect to the virtual model. Graphical tool elements 332, as an example of graphical tool elements 314, can enable a user to view and/or associate issue-level data, component-level data, task-level data, and/or communication-level data with the target location.

Data associated with the AV and/or the virtual model can include AV-specific data 183 and class-specific data 187, as previously described with reference to FIG. 1. As depicted in FIG. 3, AV-specific data 183 can include or otherwise be associated with AV-specific identifier 181 of FIG. 1 that identifies the subject AV (e.g., 140-1). Additionally, AV-specific data 183 can include other data that is associated with the subject AV or AV-specific virtual model, including an operator identifier 340 that identifies fleet operator 122 as the operator of the subject AV, issue-level data 342, component-level data 344, task-level data 346, and communication-level data 348.

As further depicted in FIG. 3, class-specific data 187 can include or otherwise be associated with class-specific identifier 185 of FIG. 1 that identifies a class of AV to which the subject AV belongs. Additionally, class-specific data 187 can include AV-specific identifiers (e.g., 181) of AVs that belong to the class of AV, as well as issue-level data 350, component-level data 352, task-level data 354, and communication-level data 356 that is associated with the class of AV.

FIG. 4 is a schematic diagram depicting additional aspects of AV-specific data 183 previously described with reference to FIGS. 1-3 for a subject AV (e.g., AV 140-1). In the example of FIG. 4, AV-specific data 183 includes issue-level data 342, component-level data 344, task-level data 346, and communication-level data 348.

Issue-level data 342 includes data that describes one or more issues with respect to the subject AV. Issue-level data 342 includes an issue list 400 that identifies the one or more issues, an example of which includes issue 402. As depicted with respect to example issue 402, various issue data 404 can be associated with each issue of issue list 400, including an issue identifier 406 that identifies the issue, an issue status 408 that identifies a current status of the issue among a plurality of predefined status identifiers (e.g., unresolved, resolved), and other issue data 410. Issue-level data 342 can further include historical issue data 412 that describes one or more past issues with respect to the subject AV that have been resolved through final disposition. Issue-level data 342 can include linking 414 to issue-level data 350 of class-specific data 187 for the class of AV to which the subject AV belongs, thereby enabling issue-level data 342 of AV-specific data 183 to form part of issue-level data 350 of class-specific data 187. In some examples, issue-level data 350 of class-specific data 187 can include issue-level data 342 for all AVs (or a plurality of AVs) of the class of AV, which can enable users to review issues across multiple AVs of the class.

Component-level data 344 includes data that describes components of the subject AV. Component-level data 344 includes a component list 420 that identifies each of the components of the subject AV, an example of which includes component 422. As depicted with respect to example component 422, various component data 424 can be associated with each component of component list 420, including a component identifier 426 that identifies the component, a component status 428 that identifies a current status of the component among a plurality of predefined status identifiers (e.g., functioning, non-functioning, and/or quantity of flight hours), and other component data 430. Other component data 430 can identify a 6DOF positioning of the component within three-dimensional reference frame 320 of the AV-specific virtual model, as an example. Additionally or alternatively, component data 430 can identify a replacement component or modification of an existing component of the subject AV. In at least some examples, component data 430 can include CAD files for components of an AV or class of AV from which AV-specific and class-specific virtual models of AVs can be generated. Component-level data 344 can further include historical component data 432 that describes one or more past components with respect to the subject AV that have been modified or replaced by a current component of the AV through final disposition. Component-level data 344 can include linking 434 to component-level data 352 of class-specific data 187 for the class of AV to which the subject AV belongs, thereby enabling component-level data 344 of AV-specific data 183 to form part of component-level data 352 of class-specific data 187. In some examples, component-level data 352 of class-specific data 187 can include component-level data 344 for all AVs (or a plurality of AVs) of the class of AV, which can enable users to review components across multiple AVs of the class.

Task-level data 346 includes data that describes tasks to be performed with respect to the subject AV. Task-level data 346 includes a task list 440 that identifies each of the tasks to be performed with respect to the subject AV, an example of which includes task 442. A task can refer to a maintenance-related task, a repair task, a component replacement task, an investigation task, a plan submission task, an approval task, or other suitable type of task with respect to the subject AV. As depicted with respect to example task 442, various task data 444 can be associated with each task of task list 440, including a task identifier 446 that identifies the task, a task status 448 that identifies a current status of the task among a plurality of predefined status identifiers (e.g., task assigned to particular personnel, task in-process, task completed), and other task data 450. In some examples, the predefined status identifiers of task status 448 can be provided for each step of a multi-step task workflow. Task-level data 346 can further include historical task data 452 that describes one or more past tasks that have been performed with respect to the subject AV through final disposition. Task-level data 346 can include linking 454 to task-level data 354 of class-specific data 187 for the class of AV to which the subject AV belongs, thereby enabling task-level data 346 of AV-specific data 183 to form part of task-level data 354 of class-specific data 187. In some examples, task-level data 354 of class-specific data 187 can include task-level data 346 for all AVs (or a plurality of AVs) of the class of AV, which can enable users to review tasks across multiple AVs of the class.

Communication-level data 348 includes data that describes and/or includes communications among users of service 112 with respect to the subject AV. Communication-level data 348 includes a communications list 460 that identifies each of the communications between users with respect to the subject AV, an example of which includes communication 462. As depicted with respect to example communication 462, various communication data 464 can be associated with each communication of communications list 460, including a communication identifier 466 that identifies the communication, a communication status 468 that identifies a current status of the communication among a plurality of predefined status identifiers (e.g., unread, read, responded to, etc.), and other communication data 470 that contains the content of the communication between two or more users. Communication-level data 348 can further include historical communication data 472 that describes one or more past communications with respect to the subject AV for matters that have progressed to final disposition. Communication-level data 348 can include linking 474 to communication-level data 356 of class-specific data 187 for the class of AV to which the subject AV belongs, thereby enabling communication-level data 348 of AV-specific data 183 to form part of communication-level data 356 of class-specific data 187. In some examples, communication-level data 356 of class-specific data 187 can include communication-level data 348 for all AVs (or a plurality of AVs) of the class of AV, which can enable users to review communications across multiple AVs of the class.

Each of issue data 404, component data 424, task data 444, and/or communication data 464 can identify a target location 480 with respect to the subject AV that is associated with issue 402, component 422, task 442, and/or communication 462, respectively. Target location 480 can refer to a particular component of the subject AV within the virtual model as identified by a component identifier 482, a particular point on or within the virtual model of the subject AV within three-dimensional reference frame 320 as identified by a point identifier 484, or a particular region on or within the virtual model of the subject AV within three-dimensional reference frame 320 as identified by region identifier 486. As described with reference to FIG. 3, a target location such as 480 can be defined or otherwise identified by a user with respect to an AV-specific virtual model or class-specific virtual model using tools 168 of service interface 162. Target location 480 can be used to associate issue data 404, component data 424, task data 444, and/or communication data 464 with a particular component, point, or region of the subject AV within the AV-specific virtual model in addition to being generally associated with the subject AV via the AV-specific identifier. Accordingly, target location 480 with respect to the virtual model of the subject AV can be associated with any combination of one or more issues, one or more components, one or more tasks, and/or one or more components that can be viewed or interacted with in the context of graphical representations of an AV-specific virtual model.

Each of issue data 404, component data 424, task data 444, and/or communication data 464 can include various content 490 that is associated with issue 402, component 422, task 442, and/or communication 462, respectively. Content 490 can include text content 492, image content 494, video content 496, and/or other content 498. Content 490 can be input and/or uploaded by users via their respective client devices, as an example. Text content 492 includes human speech in text form that can describe aspects of issue 402, component 422, and/or task 442, and can contain the text content of communication 462. Image content 494 can include one or more images that provide a visual account of the subject AV or a portion thereof. Video content 496 can include one or more videos that provide a visual and/or audio account of the subject AV or a portion thereof. Other content 498 can include files of other suitable type and/or format, including documents or audio that does not include a video component.

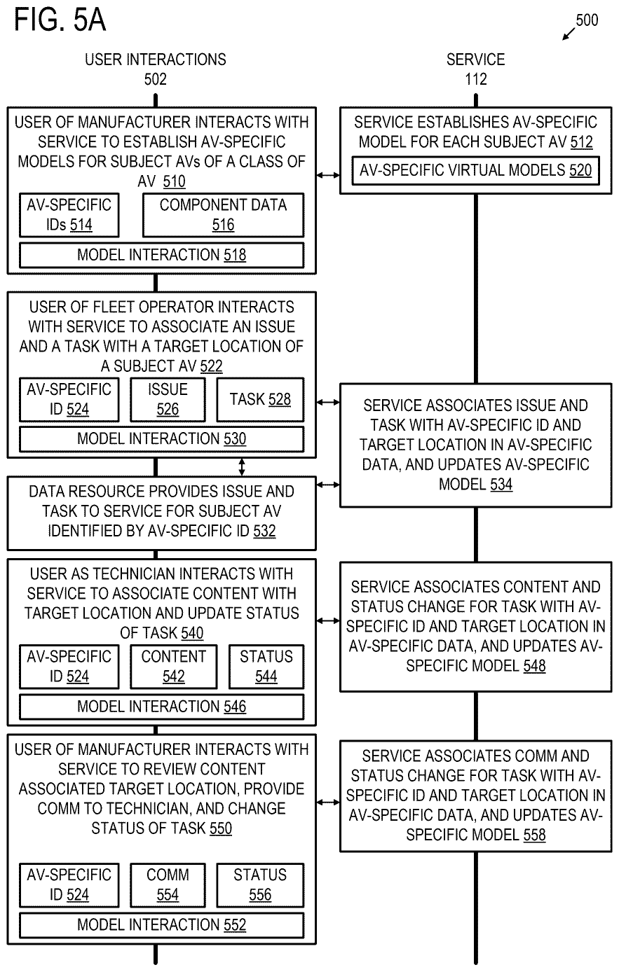

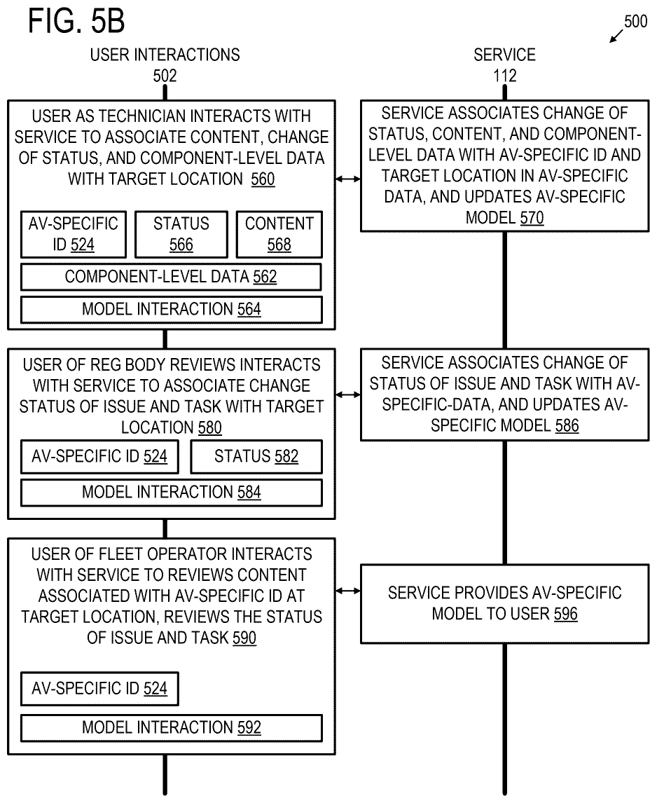

FIGS. 5A and 5B are flow diagrams depicting an example collaborative workflow 500 between various users as personnel of manufacturer 120, fleet operator 122, technicians 124, and regulatory body 126 that is enabled by service 112 of FIG. 1. In FIGS. 5A and 5B, operations performed by service 112 are schematically depicted in the right-hand column, and user interactions 502 with service 112 that are provided via client devices over communications network 158 are schematically depicted in the left-hand column. User interactions 502 can include user input directed by users to an instance of service interface 162 of FIG. 1, including tools 168 and/or graphical representation 170 of a virtual model presented at a respective client device.

Referring to FIG. 5A, at 510, a user, as personnel of manufacturer 120, interacts with service 112 via a client device to establish AV-specific virtual models 520 for each of a plurality of subject AVs of a class of AV. As an example, the plurality of subject AVs are operated by fleet operator 122 in which the subject AVs include a different component or modification of a component that is not present in other AVs of the class of AV. At 510, as part of interacting with service 112, the user provides a plurality of AV-specific identifiers 514 for the plurality of subject AVs of the class of AV, and component-level data 516 (e.g., 344 of FIGS. 3 and 4).

At 512, service 112 establishes an AV-specific virtual model in database 116 for each subject AV identified by an AV-specific identifier within the plurality of AV-specific identifiers 514 by performing method 200 of FIG. 2. As an example, service 112 performs operations 210-240 of method 200 for each AV-specific identifier of 514 to generate and store an AV-specific virtual model of 520 in database 116 that is associated with the AV-specific identifier.

Interaction of the user at 510 with service 112 to establish AV-specific virtual models 520 can include the user providing component-level data 516 to service 112 through model interaction 518 with the class-specific virtual model, as described at operations 226 and 228 of method 200. Component-level data 516 can define aspects of the different component or component modification for the plurality of subject AVs that distinguishes them from other AVs of the class. Component-level data 516 is an example of an AV-specific data item (e.g., 196 of FIG. 1) that can be received by service 112 at operation 228 of method 200. In further examples, service 112 can support batch processing of a plurality of AV-specific identifiers to establish AV-specific virtual models 520 in database 116 for a plurality of subject AVs. Additionally, model interaction 518 can include the user interacting with each of the AV-specific virtual models output at operation 240 of method 200 to confirm that AV-specific virtual models 520 were accurately generated.

At 522, a user, as personnel of fleet operator 122, interacts with service 112 to associate an issue and a task with a target location of the subject AV within the AV-specific virtual model. As part of the user interaction at 522, the user can provide AV-specific identifier 524 of AV-specific identifiers 514 for which AV-specific virtual models were established at 520. Additionally, user interaction at 522 can include model interaction 530 with the AV-specific virtual model for AV-specific identifier 524 to associate issue 526 and task 528 with the target location within the AV-specific virtual model. In this example, issue 526 and task 528 are examples of AV-specific data items that can be received at operation 228. In another example, indicated at 530, AV-specific identifier 524, issue 526, and task 528 can be provided by user interaction at 522 to a data resource (e.g., 148) of fleet operator 122, which in-turn provides AV-specific identifier 524, issue 526, and task 528 to service 112.

At 534, service 112 associates issue 526 and task 528 with AV-specific identifier 524 and with the target location within AV-specific data to obtain updated AV-specific data. In some examples, service 112 can set an initial status for issue 526 and an initial status for task 528 within the AV-specific data. As an example, the initial status for issue 526 can indicate an unresolved status. As another example, task 528 can include an initial investigation task to be performed by a particular technician or set of technicians, and the initial status for the task can indicate a pending status with respect to the initial investigation task. Additionally, at 534, service 112 updates the AV-specific virtual model based on the AV-specific data, including issue 526 and task 528, as previously described with reference to operation 252 of method 200 to obtain an updated AV-specific model. For example, service 112 can include a graphical indicator at the target location within the AV-specific model to indicate that issue 526 and/or task 528 are associated with that target location.

At 540, a user, as personnel of technicians 124, interacts with service to associate content (e.g., text, images, videos, etc.) with the target location within the AV-specific virtual model, and to update the status of the task. As part of the user interaction at 540, the user can provide AV-specific identifier 524 for the subject AV to service 112, and content 542 and status 544 as examples of AV-specific data items. User interaction at 540 can include model interaction 546 in which the user interacts with the AV-specific virtual model that was previously updated at 534. As an example, status 544 can indicate that an initial investigation task with respect to the target location for issue 526 has been completed.

At 548, service 112 associates content 542 and the change of status 544 with AV-specific identifier 524 and with the target location in the AV-specific data. Additionally, at 548, service 112 updates the AV-specific virtual model to reflect content 542 and change of status 544.

At 550, a user, as personnel of manufacturer 120, interacts with service 112 to review content 542 associated with the target location, provide a communication to the technician, and change the status of the task. As part of the user interaction at 550, the user can provide AV-specific identifier 524 for the subject AV to service 112, communications 554 and the change of status 556 of the task as examples of AV-specific data items. User interaction at 550 can include model interaction 552 in which the user interacts with the AV-specific virtual model that was previously updated at 548. As an example, status 546 can indicate that the manufacturer has reviewed content 542 associated with the target location, and communication 554 can identify a recommended course of action with respect to resolving issue 526 associated with the target location.

At 558, service 112 associates communication 554 and the change of status 556 with AV-specific identifier 524 and with the target location in the AV-specific data. Additionally, at 558, service 112 updates the AV-specific virtual model to reflect communication 554 and change of status 556.

FIG. 5B is a continuation of collaborative workflow 500 from FIG. 5A.

At 560, a user, as personnel of technicians 124, interacts with service 112 to associate content, change of status, and component-level data with the target location of AV-specific identifier 524. As part of the user interaction at 560, the user can provide AV-specific identifier 524 for the subject AV to service 112, content 568 (e.g., text, images, videos, etc.), change of status 566 of the task and of the issue, and component-level data 562 as examples of AV-specific data items. User interaction at 560 can include model interaction 564 in which the user interacts with the AV-specific virtual model that was previously updated at 558. As an example, content can include text commentary, images, and/or videos of the target location following resolution of the issue by the technician. Additionally, in this example, the change of status can indicate that the task has been completed by the technician and that the issue has been resolved. Component-level data 562 can include a component identifier of a replacement component or repaired component, as an example. Additionally, component-level data 562 can include a file that represents a virtual model of the replacement component, which can be incorporated into the AV-specific virtual model.

At 570, service 112 associates change of status 566, content 568, and component-level data 562 with AV-specific identifier 524 and with the target location in the AV-specific data. Additionally, at 570, service 112 updates the AV-specific virtual model to reflect change of status 566, content 568, and component-level data 562.

At 580, a user, as personnel of regulatory body 126, interacts with service 112 to associate change of status 582 of the task and issue with the target location of AV-specific identifier 524. As part of the user interaction at 580, the user can provide AV-specific identifier 524 for the subject AV to service 112, and change of status 582 of the issue and task as examples of AV-specific data items. User interaction at 580 can include model interaction 584 in which the user interacts with the AV-specific virtual model that was previously updated at 570. As an example, the user can review content 568, content 542, communication 554, and component-level data 562 as part of an approval task and final disposition of the issue associated with the target location of the subject AV. In this example, the change of status 582 can indicate that the approval task has been complete and that issue has been resolved through final disposition.

At 586, service 112 associates the change of status 582 of the issue and task with the AV-specific data for AV-specific identifier 524, and updates the AV-specific model to reflect the change of status.

At 590, a user, as personnel of fleet operator 122 interacts with service 112 to review content 568 associated with the target location of the subject AV, and the final disposition of the issue and task by providing AV-specific identifier 524 to the service. User interaction at 590 can include model interaction 592 in which the user interacts with the AV-specific virtual model previously updated at 586. At 596, service 112 provides the AV-specific virtual model that was previously updated at 586 to the user in response to receiving a request to view the model that is accompanied by AV-specific identifier 524.

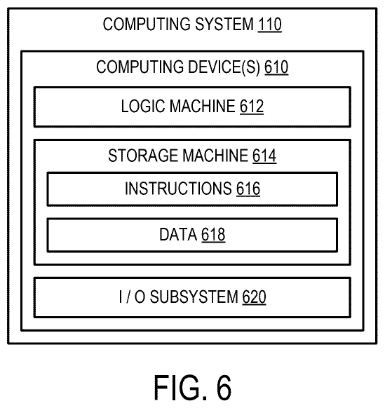

The methods and operations described herein can be performed by a computing system of one or more computing devices, such as computing system 110 of FIG. 1. For example, the methods and operations described herein can be performed by service 112 of computing system 110. FIG. 6 schematically depicts additional aspects of computing system 110.

Computing system 110 includes one or more computing devices 610, that can take the form of one or more server computing devices, personal computing devices, network computing devices, or other computing devices. Computing system 110 includes a logic machine 612, a storage machine 614 having instructions 616 and other data 618 stored thereon, and an input/output subsystem 620 that can form components of computing devices 610.

Logic machine 612 takes the form of one or more physical devices configured to execute instructions 616 and process data 618. For example, the logic machine can be configured to execute instructions 616 that are part of one or more programs 114 of FIG. 1. Instructions 616 can be executed by logic machine 612 to perform a task, implement a data type, transform the state of one or more components, achieve a technical effect, or otherwise arrive at a desired result. As an example, programs 114 of FIG. 1 are an example of instructions 616 that are executed by logic machine 612 to instantiate service 112 that can perform the methods and operations described herein. In FIG. 6, data 618 of storage machine 614 includes database 116 and associated data of FIG. 1.

Logic machine 612 can include one or more processor devices configured to execute software instructions. Additionally or alternatively, logic machine 612 can include one or more hardware or firmware logic machines configured to execute hardware or firmware instructions. Processor devices of logic machine 612 can be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage machine 614 takes the form of one or more physical devices configured to hold instructions 616 executable by logic machine 612. Storage machine 614 can include removable and/or built-in devices. Storage machine 614 can include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), as examples. Storage machine 614 can include volatile, nonvolatile, dynamic, static, read/write, read-only, random-access, sequential-access, location-addressable, file-addressable, and/or content-addressable devices.

In some examples, logic machine 612 and storage machine 614 can be integrated together into one or more hardware-logic components. Such hardware-logic components can include field-programmable gate arrays (FPGAs), program-and application-specific integrated circuits (PASIC/ASICs), program-and application-specific standard products (PSSP/ASSPs), system-on-a-chip (SOC), and complex programmable logic devices (CPLDs), for example.

The terms “module,” “program,” and “engine” can be used to describe an aspect of computing system 110 implemented to perform a particular function. In some cases, a module, program, or engine may be instantiated by logic machine 612 executing instructions 616 held by storage machine 614. The term “service”, as used herein, can be executable across multiple user sessions.

Input/output subsystem 620 can include interface devices that can communicatively couple computing system 110 with other computing devices, computing systems, input devices, output devices, and communications networks. For example, input/output subsystem 620 enables computing system 110 to send messages to and receive messages from other devices via communications network 158.

The following examples are disclosed herein.

Example 1. A method performed by a computing system, the method comprising: for a subject aeronautical vehicle (AV), receiving an AV-specific identifier that identifies the subject AV of a class of AV; retrieving, based on the AV-specific identifier, a class-specific virtual model for the class of AV; receiving an AV-specific data item to be associated with the subject AV, wherein the AV-specific data item distinguishes the subject AV from other AVs of the class of AV; generating an AV-specific virtual model by augmenting the class-specific virtual model with the AV-specific data item to obtain the AV-specific virtual model of the subject AV that incorporates the AV-specific data item; and outputting the AV-specific virtual model for presentation as a graphical representation of the subject AV.

Example 2. The method of Example 1, wherein augmenting the class-specific virtual model with the AV-specific data item includes incorporating a graphical identifier that identifies the AV-specific data item into the class-specific virtual model at a target location to obtain the AV-specific virtual model.

Example 3. The method of any of Examples 1-2, wherein the target location identifies a component, a point, or a region on or within the AV-specific virtual model.

Example 4. The method of any of Examples 1-3, the AV-specific data item includes issue-level data that identifies an issue with respect to the subject AV at a target location within the AV-specific virtual model.

Example 5. The method of Example 4, wherein the issue-level data identifies a status or a change of status of the issue.

Example 6. The method of any of Examples 1-5, wherein the AV-specific data item includes component-level data with respect to a component of the subject AV at a target location within the AV-specific virtual model.

Example 7. The method of Example 6, wherein the component-level data identifies a replacement component or modification of an existing component of the subject AV.

Example 8. The method of any of Examples 1-7, wherein the AV-specific data item includes task-level data with respect to a task to be performed with respect to a target location within the AV-specific virtual model.

Example 9. The method of Example 8, wherein the task-level data identifies a status or change of status of the task.

Example 10. The method of any of Examples 1-9, wherein the AV-specific data item includes communication-level data includes a communication between users to be associated with a target location within the AV-specific virtual model.

Example 11. The method of any of Examples 1-10, wherein outputting the AV-specific virtual model includes sending the AV-specific virtual model to a client device over a communications network for presentation at the client device as the graphical representation of the subject AV.

Example 12. The method of any of Examples 1-11, wherein retrieving the class-specific virtual model includes: retrieving a plurality of files that define the class-specific virtual model; and assembling the plurality of files to obtain the class-specific virtual model.

Example 13. The method of any of Examples 1-12, further comprising, following generating the AV-specific virtual model: storing the AV-specific virtual model in a database in association with the AV-specific identifier; receiving the AV-specific identifier; retrieving, based on the AV-specific identifier, the AV-specific virtual model from the database; receiving a subsequent AV-specific data item to be associated with the subject AV; updating the AV-specific virtual model by augmenting the AV-specific virtual model retrieved from the database with the subsequent AV-specific data item to obtain an updated AV-specific virtual model of the subject AV that incorporates the subsequent AV-specific data item; and outputting the updated AV-specific virtual model for presentation as a graphical representation of the subject AV.

Example 14. A computing system, comprising: one or more computing devices configured to: for a subject aeronautical vehicle (AV), receive an AV-specific identifier that identifies the subject AV of a class of AV; retrieve, based on the AV-specific identifier, a class-specific virtual model for the class of AV; receive an AV-specific data item to be associated with the subject AV, wherein the AV-specific data item distinguishes the subject AV from other AVs of the class of AV; generate an AV-specific virtual model by augmenting the class-specific virtual model with the AV-specific data item to obtain the AV-specific virtual model of the subject AV that incorporates the AV-specific data item; and output the AV-specific virtual model for presentation as a graphical representation of the subject AV.

Example 15. The computing system of Example 14, wherein the class-specific virtual model is augmented with the AV-specific data item by incorporating a graphical identifier that identifies the AV-specific data item into the class-specific virtual model at a target location to obtain the AV-specific virtual model; and wherein the target location identifies a component, a point, or a region on or within the AV-specific virtual model.

Example 16. The computing system of any of Examples 14-5, wherein the AV-specific data item includes one or more of issue-level data, component-level data, task-level data, and/or communication-level data with respect to the subject AV at a target location within the AV-specific virtual model.

Example 17. A method performed by a computing system, the method comprising: for a subject aeronautical vehicle (AV), receiving an AV-specific identifier that identifies the subject AV of a class of AV; retrieving, based on the AV-specific identifier, an AV-specific virtual model for the subject AV from a database, wherein the AV-specific virtual model was previously generated by augmenting a class-specific virtual model for the class of AV with one or more AV-specific data items that distinguish the subject AV from other AVs of the class of AV; receiving a subsequent AV-specific data item to be associated with the subject AV; updating the AV-specific virtual model by augmenting the AV-specific virtual model retrieved from the database with the subsequent AV-specific data item to obtain an updated AV-specific virtual model of the subject AV that incorporates the subsequent AV-specific data item; and outputting the updated AV-specific virtual model for presentation as a graphical representation of the subject AV.

Example 18. The method of Example 17, wherein augmenting the AV-specific virtual model with the subsequent AV-specific data item includes incorporating a graphical identifier that identifies the subsequent AV-specific data item into the AV-specific virtual model at a target location to obtain the updated AV-specific virtual model; and wherein the target location identifies a component, a point, or a region on or within the AV-specific virtual model.

Example 19. The method of any of Examples 17-18, wherein the AV-specific data item includes one or more of issue-level data, component-level data, task-level data, and/or communication-level data with respect to the subject AV at a target location within the updated AV-specific virtual model.

Example 20. The method of Example 19, wherein the AV-specific data item identifies a status or a change of status with respect to one or more of: an issue with respect to the subject AV identified by the issue-level data, a component of the subject AV identified by the component-level data, a task to be performed with respect to the subject AV identified by the task-level data, a communication between users with respect to the subject AV; and wherein the method further comprises: associating the status or change of status with the target location of the subject AV within the updated AV-specific virtual model.

Example 21. A storage machine for a computing system, wherein the storage machine has instructions stored thereon executable by a logic machine of the computing system to perform any of the methods of Examples 1-13 and 17-20.

It will be understood that the configurations and/or approaches described herein are exemplary in nature, and that disclosed examples are not to be considered in a limiting sense, because numerous variations are possible. The specific methods and flow diagrams described herein can represent one or more of any number of processing strategies. As such, various acts illustrated and/or described can be performed in the sequence illustrated and/or described, in other sequences, in parallel, or omitted. Likewise, the order of the above-described operations can be changed.

The subject matter of the present disclosure includes all novel and non-obvious combinations and sub-combinations of the various systems, methods, and configurations, and other features, functions, acts, and/or properties disclosed herein, as well as any and all equivalents thereof.

1. A method performed by a computing system, the method comprising:
for a subject aeronautical vehicle (AV), receiving an AV-specific identifier that identifies the subject AV of a class of AV;
retrieving, based on the AV-specific identifier, a class-specific virtual model for the class of AV;
receiving an AV-specific data item to be associated with the subject AV, wherein the AV-specific data item distinguishes the subject AV from other AVs of the class of AV;
generating an AV-specific virtual model by augmenting the class-specific virtual model with the AV-specific data item to obtain the AV-specific virtual model of the subject AV that incorporates the AV-specific data item; and
outputting the AV-specific virtual model for presentation as a graphical representation of the subject AV.

2. The method of claim 1, wherein augmenting the class-specific virtual model with the AV-specific data item includes incorporating a graphical identifier that identifies the AV-specific data item into the class-specific virtual model at a target location to obtain the AV-specific virtual model.

3. The method of claim 1, wherein the target location identifies a component, a point, or a region on or within the AV-specific virtual model.

4. The method of claim 1, the AV-specific data item includes issue-level data that identifies an issue with respect to the subject AV at a target location within the AV-specific virtual model.

5. The method of claim 4, wherein the issue-level data identifies a status or a change of status of the issue.

6. The method of claim 1, wherein the AV-specific data item includes component-level data with respect to a component of the subject AV at a target location within the AV-specific virtual model.

7. The method of claim 6, wherein the component-level data identifies a replacement component or modification of an existing component of the subject AV.

8. The method of claim 1, wherein the AV-specific data item includes task-level data with respect to a task to be performed with respect to a target location within the AV-specific virtual model.

9. The method of claim 8, wherein the task-level data identifies a status or change of status of the task.

10. The method of claim 1, wherein the AV-specific data item includes communication-level data includes a communication between users to be associated with a target location within the AV-specific virtual model.

11. The method of claim 1, wherein outputting the AV-specific virtual model includes sending the AV-specific virtual model to a client device over a communications network for presentation at the client device as the graphical representation of the subject AV.

12. The method of claim 1, wherein retrieving the class-specific virtual model includes:
retrieving a plurality of files that define the class-specific virtual model; and
assembling the plurality of files to obtain the class-specific virtual model.

13. The method of claim 1, further comprising, following generating the AV-specific virtual model:
storing the AV-specific virtual model in a database in association with the AV-specific identifier;
receiving the AV-specific identifier;
retrieving, based on the AV-specific identifier, the AV-specific virtual model from the database;
receiving a subsequent AV-specific data item to be associated with the subject AV;
updating the AV-specific virtual model by augmenting the AV-specific virtual model retrieved from the database with the subsequent AV-specific data item to obtain an updated AV-specific virtual model of the subject AV that incorporates the subsequent AV-specific data item; and
outputting the updated AV-specific virtual model for presentation as a graphical representation of the subject AV.

14. A computing system, comprising:
one or more computing devices configured to:
for a subject aeronautical vehicle (AV), receive an AV-specific identifier that identifies the subject AV of a class of AV;
retrieve, based on the AV-specific identifier, a class-specific virtual model for the class of AV;
receive an AV-specific data item to be associated with the subject AV, wherein the AV-specific data item distinguishes the subject AV from other AVs of the class of AV;
generate an AV-specific virtual model by augmenting the class-specific virtual model with the AV-specific data item to obtain the AV-specific virtual model of the subject AV that incorporates the AV-specific data item; and
output the AV-specific virtual model for presentation as a graphical representation of the subject AV.

15. The computing system of claim 14, wherein the class-specific virtual model is augmented with the AV-specific data item by incorporating a graphical identifier that identifies the AV-specific data item into the class-specific virtual model at a target location to obtain the AV-specific virtual model; and
wherein the target location identifies a component, a point, or a region on or within the AV-specific virtual model.

16. The computing system of claim 14, wherein the AV-specific data item includes one or more of issue-level data, component-level data, task-level data, and/or communication-level data with respect to the subject AV at a target location within the AV-specific virtual model.

17. A method performed by a computing system, the method comprising:
for a subject aeronautical vehicle (AV), receiving an AV-specific identifier that identifies the subject AV of a class of AV;
retrieving, based on the AV-specific identifier, an AV-specific virtual model for the subject AV from a database, wherein the AV-specific virtual model was previously generated by augmenting a class-specific virtual model for the class of AV with one or more AV-specific data items that distinguish the subject AV from other AVs of the class of AV;
receiving a subsequent AV-specific data item to be associated with the subject AV;
updating the AV-specific virtual model by augmenting the AV-specific virtual model retrieved from the database with the subsequent AV-specific data item to obtain an updated AV-specific virtual model of the subject AV that incorporates the subsequent AV-specific data item; and
outputting the updated AV-specific virtual model for presentation as a graphical representation of the subject AV.

18. The method of claim 17, wherein augmenting the AV-specific virtual model with the subsequent AV-specific data item includes incorporating a graphical identifier that identifies the subsequent AV-specific data item into the AV-specific virtual model at a target location to obtain the updated AV-specific virtual model; and
wherein the target location identifies a component, a point, or a region on or within the AV-specific virtual model.

19. The method of claim 17, wherein the AV-specific data item includes one or more of issue-level data, component-level data, task-level data, and/or communication-level data with respect to the subject AV at a target location within the updated AV-specific virtual model.

20. The method of claim 19, wherein the AV-specific data item identifies a status or a change of status with respect to one or more of:
an issue with respect to the subject AV identified by the issue-level data,
a component of the subject AV identified by the component-level data,
a task to be performed with respect to the subject AV identified by the task-level data,
a communication between users with respect to the subject AV; and
wherein the method further comprises:
associating the status or change of status with the target location of the subject AV within the updated AV-specific virtual model.
